(19) United States
(12) Patent Application Publication
(10) Pub. No.: US 2025/0316443 A1
(43) Pub. Date: Oct. 9, 2025

(54) SCANNING ELECTRON MICROSCOPE (SEM) IMAGE IMPROVING METHOD

(71) Applicant: SAMSUNG ELECTRONICS CO, LTD., Suwon-si (KR)

(72) Inventors: Sewon KIM, Suwon-si (KR); Kyoung Mu LEE, Suwon-si (KR); Kang Geon LEE, Suwon-si (KR); Wooseok LEE, Suwon-si (KR); Kwangeun KIM, Suwon-si (KR); Minsun PARK, Suwon-si (KR); Sungeun LEE, Suwon-si (KR)

(73) Assignees: SAMSUNG ELECTRONICS CO, LTD., Suwon-si (KR); SEOUL NATIONAL UNIVERSITY R& DB FOUNDATION, Seoul (KR)

(21) Appl. No.: 18/905,665

(22) Filed: Oct. 3, 2024

(30) Foreign Application Priority Data
Apr. 3, 2024 (KR) 10-2024-0045523

(51) Int. Cl. H01J 37/22; H01J 37/28

(52) U.S. Cl. CPC H01J 37/222; H01J 37/28; H01J 2237/0455

(57) ABSTRACT

A method of improving an SEM image includes (a) measuring a first SEM image, (b) determining a noise correlation length with respect to the first SEM image, (c) based on the noise correlation length being greater than 0, adjusting an aperture signal of an SEM equipment, and repeating (a), (b) and (c) until the noise correlation length is substantially 0.

### CROSS-REFERENCE TO RELATED APPLICATION

This application is based on and claims priority under 35 U.S.C. § 119 to Korean Patent Application No. 10-2024-0045523, filed on Apr. 3, 2024, in the Korean Intellectual Property Office, the disclosure of which is incorporated by reference herein in its entirety.

### BACKGROUND

Example embodiments of the disclosure relate to a scanning electron microscope (SEM) image, and particularly, to a method of improving an SEM image.

An SEM may refer to a type of electron microscope configured to scan the surface of a sample by using an electron beam (E-beam) to image the surface of the sample. For example, an SEM analysis method may refer to a method of shooting electrons by a high-speed electron gun, and detecting and analyzing particles, such as secondary electrons, projected from a sample after collision and interaction of the electrons with the surface of the sample. Recently, along with an increase in the measurement speed of an SEM image, SEM images containing noise have been generated. In addition, due to critical dimension (CD) measurement based on an SEM image containing noise, errors in the CD measurement frequently occur.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a scanning electron microscope (SEM) image improving method that may be capable of improving the consistency of critical dimension (CD) measurement for a semiconductor pattern by improving an SEM image.

Additional aspects will be set forth in part in the description which follows and, in part, will be apparent from the description, or may be learned by practice of the presented embodiments.

According to an aspect of an example embodiment, a method of improving an SEM image may include (a) measuring a first SEM image, (b) determining a noise correlation length with respect to the first SEM image, (c) based on the noise correlation length being greater than 0, adjusting an aperture signal of an SEM equipment, and repeating (a), (b) and (c) until the noise correlation length is substantially 0.

According to an aspect of an example embodiment, a method of improving an SEM image may include measuring a first SEM image, determining a noise correlation length with respect to the first SEM image, and based on the noise correlation length being substantially 0, setting a reference score by performing a first quality evaluation on the first SEM image, fixing the aperture signal, setting n to 1, n being an integer corresponding to a frame, measuring an SEM image of an nth frame, canceling white noise in the SEM image of the nth frame, performing a second quality evaluation on the SEM image of the nth frame, based on n being less than N, increasing n by 1 and changing a measurement condition of an SEM equipment, N being an integer that is greater than or equal to 2, based on n being greater than or equal to N, selecting a measurement condition corresponding to an SEM image of a best-quality frame among SEM images of the N frames, and measuring the SEM image of the nth frame based on the selected measurement condition of the SEM equipment.

According to an aspect of an example embodiment, a method of improving an SEM image may include measuring a first SEM image, determining a noise correlation length with respect to the first SEM image based on unsupervised learning, based on the noise correlation length being substantially 0, setting a reference score by performing a first quality evaluation on the first SEM image, performing measurement and second quality evaluation on SEM images of N frames while fixing the aperture signal and changing a measurement condition, and measuring an SEM image based on the changed measurement condition.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating a method of improving a scanning electron microscope (SEM) image according to one or more embodiments;

FIG. 2 is a conceptual diagram illustrating the method of improving an SEM image of FIG. 1 in conjunction with SEM equipment according to one or more embodiments;

FIGS. 3A and 3B are diagrams illustrating a cause by which noise is included in an SEM image, according to one or more embodiments;

FIGS. 4A and 4B are diagrams illustrating a method of reducing or canceling noise in an SEM image, according to one or more embodiments;

FIG. 5 is a diagram illustrating a method of improving an SEM image in conjunction with SEM equipment according to one or more embodiments;

FIGS. 6A to 6C are diagrams illustrating a method of determining a noise correlation length, according to one or more embodiments;

FIG. 7 is a flowchart illustrating a method of improving an SEM image according to one or more embodiments;

FIG. 8 is a flowchart illustrating performing measurement and quality evaluation on SEM images of N frames according to one or more embodiments;

FIG. 9A illustrates an SEM image containing noise due to an inter-pixel interference signal and a learning result image obtained through unsupervised learning based on the SEM image;

FIG. 9B illustrates an image undergoing a noise cancelation process and a learning result image obtained through unsupervised learning based on the noise-canceled SEM image according to one or more embodiments; and

FIG. 10 is a block diagram of an SEM image measurement system, according to one or more embodiments

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

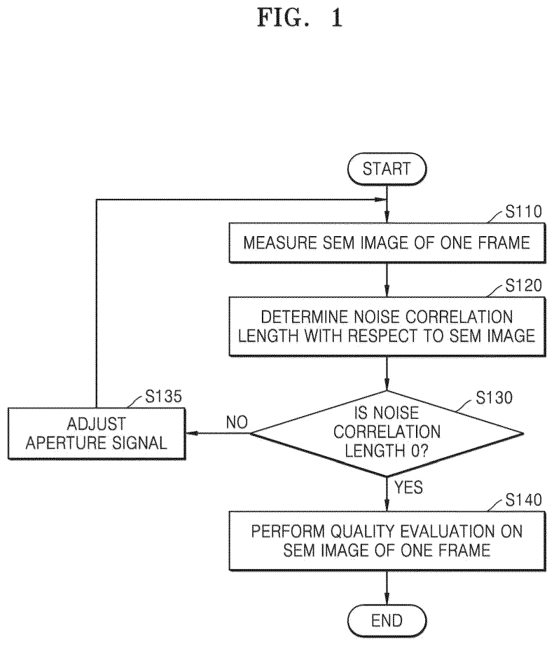

FIG. 1 is a flowchart illustrating a method of improving a scanning electron microscope (SEM) image according to one or more embodiments.

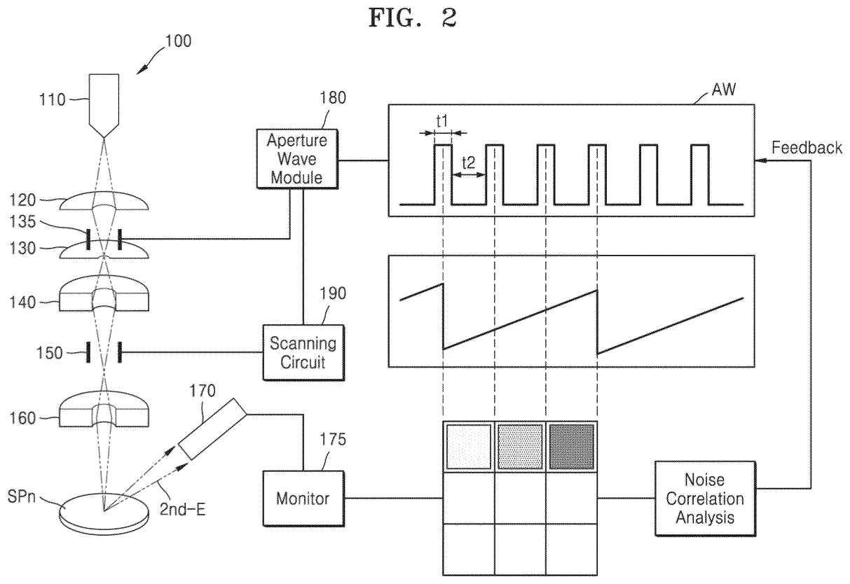

Referring to FIG. 1, the method of improving an SEM image according to one or more embodiments may include first measuring an SEM image of one frame for patterns on a sample (SPn of FIG. 2) through SEM equipment (100 of FIG. 2) in operation S110. The SEM image of the one frame may include a plurality of pixels (PX of FIG. 2) included in a two-dimensional array structure. The measurement of the SEM image of the one frame may be performed based on a set aperture signal. Herein, the aperture signal may correspond a periodic pulse signal for adjusting electrons from an electron gun (110 of FIG. 2) to pass through an aperture (130 of FIG. 2). The aperture signal may be applied from an aperture wave module (180 of FIG. 2) to an aperture block coil (135 of FIG. 2) on the aperture 130. For example, when the voltage of the aperture signal in a block interval is applied to the aperture block coil 135, electrons may be biased by an electromagnetic field and may not pass through the aperture 130. The measuring of the SEM image through the SEM equipment 100 is described in more detail with reference to FIGS. 2 to 4B.

After the measurement of the SEM image of the one frame, a noise correlation length with respect to the SEM image may be determined in operation S120. Herein, the noise correlation length may indicate the correlation length between adjacent noise signals in a pixel unit. For example, a noise image of one frame may be obtained, then a pixel position may shifted by one pixel at a time (i.e., iterative shifting by one pixel) to obtain the correlation between adjacent noise signals, and the correlation may be determined as a noise correlation length when the correlation is greater than or equal to a certain threshold. Such noise correlation of an SEM image may be caused by a voltage signal of an adjacent pixel when the SEM image is obtained. Accordingly, a noise correlation length may be referred to as an inter-pixel correlation length, a noise interference length, or the like.

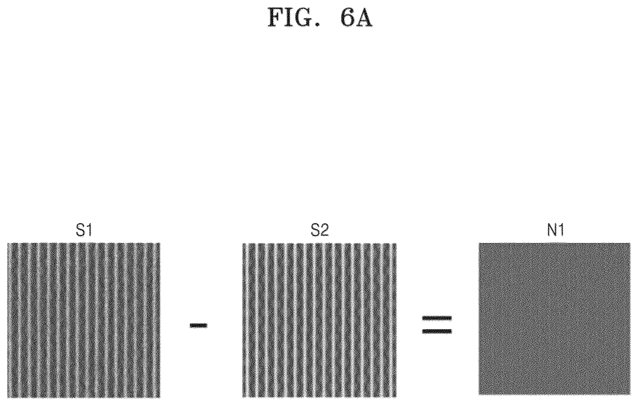

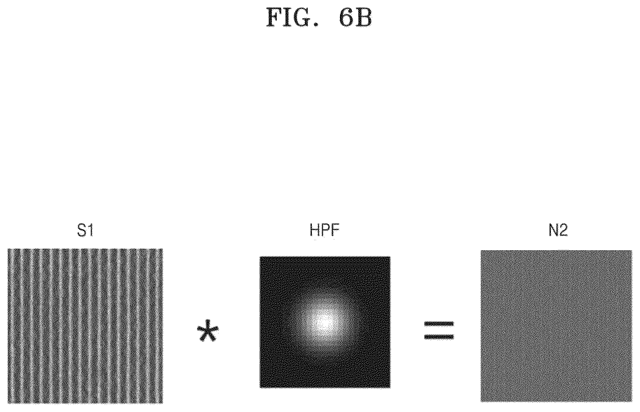

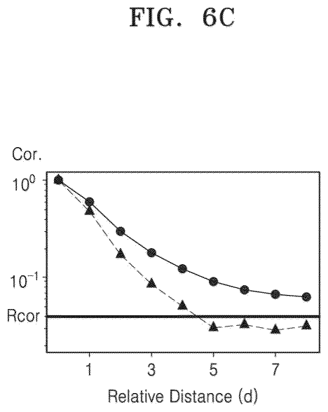

A noise correlation length may be determined through inter-image signal processing. A process of determining a noise correlation length through inter-image signal processing is described in more detail with reference to FIGS. 6A to 6C.

The noise correlation length may be obtained through unsupervised learning on the previously obtained SEM image of the one frame. As a reference, the unsupervised learning is a training method with an unknown label of data, may have higher difficulty than supervised learning, and may also have difficulty in result analysis. The unsupervised learning may be classified into clustering, dimensionality reduction, association rule, and the like according to objectives. In the Method of improving an SEM image according to one or more embodiments, to determine the noise correlation length, the clustering of the unsupervised learning may be used, and similarity measurement in a clustering process may also be used. For example, in the similarity measurement in the clustering process, Euclidean distance, Minkowski distance, Manhattan distance, Mahalanobis distance, 1-correlation, or the like may be used.

After the determining of the noise correlation length, the system may determine in operation S130 whether the noise correlation length is substantially 0. Herein, the noise correlation length being substantially 0 may indicate the current pixel is not influenced from an adjacent pixel. The noise correlation length not being 0 may indicate that the current pixel is influenced from an adjacent pixel.

When the noise correlation length is not substantially 0 or 0 (NO in operation S130), an aperture signal may be adjusted in operation S135. For example, in the aperture signal, the time (t1 of FIG. 2) of a block interval may be increased to increase the time for which electrons are blocked by the aperture 130. After the adjusting of the aperture signal, the method of improving an SEM image may repeat operation S110 of measuring an SEM image such that an SEM image of one frame is measured again. An aperture signal may be the aperture signal adjusted in operation S135 of adjusting the aperture signal. For example, the aperture signal may have the time t1 of the block interval, which has increased more than the previous iteration of the method.

Operation S110 of measuring an SEM image of one frame to operation S135 of adjusting an aperture signal may be repeatedly performed until the noise correlation length is substantially 0 or 0.

When the noise correlation length is substantially 0 or 0 (YES in operation S130), quality evaluation on the SEM image of the one frame may be performed in operation S140. The quality evaluation on the SEM image may be performed through, for example, peak signal-to-noise ratio (PSNR) determination. However, the quality evaluation on the SEM image is not limited to the PSNR determination. In addition, the quality evaluation on the SEM image may be digitized and set as a reference score. For example, a PSNR determination value for an SEM image of one frame of which the noise correlation length is 0 (or substantially 0) for the first time may be set as the reference score.

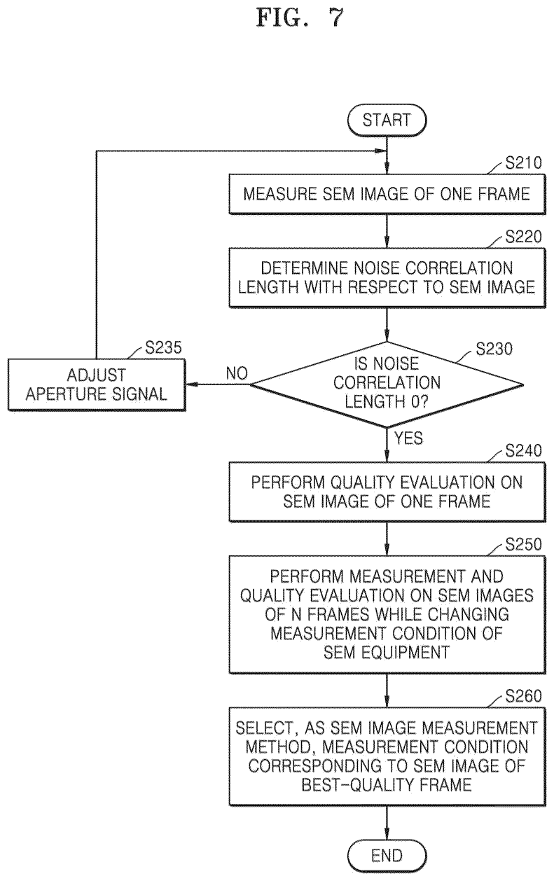

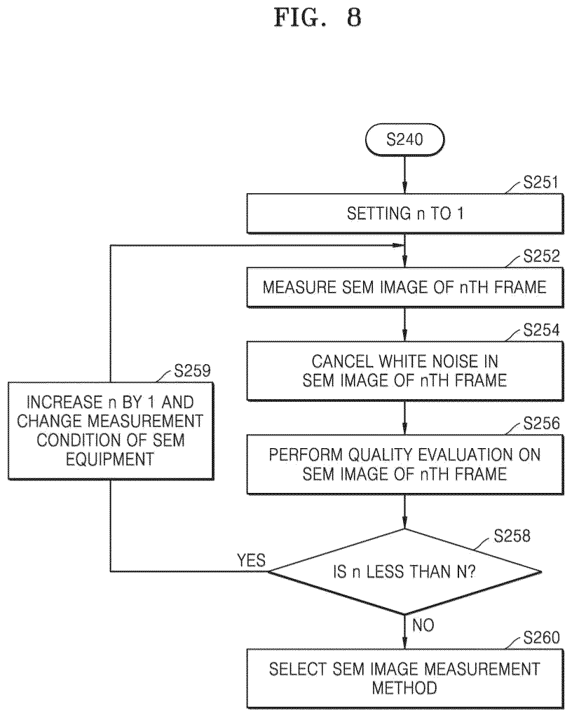

Thereafter, a white noise cancelation process on the SEM image may be performed. The white noise cancelation process may be performed on SEM images of a plurality of frames while changing a measurement condition of SEM equipment. In addition, an optimal SEM image measurement method may be selected based on an SEM image of a best-quality frame. The white noise cancelation process and the selection of the optimal SEM image measurement method are described in more detail with reference to FIGS. 7 and 8.

The method of improving an SEM image according to one or more embodiments may obtain an SEM image without inter-pixel noise by determining a noise correlation length in an SEM image of one frame and adjusting an aperture signal until the noise correlation length is 0 or substantially. Therefore, white noise in the SEM image may be canceled thereafter to obtain a high-quality SEM image, thereby improving critical dimension (CD) measurement consistency in CD measurement on a semiconductor pattern.

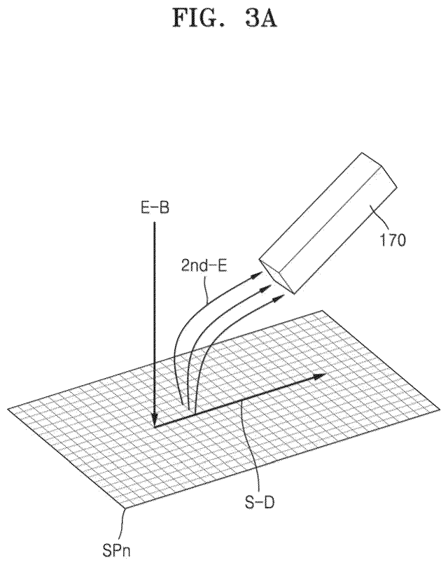

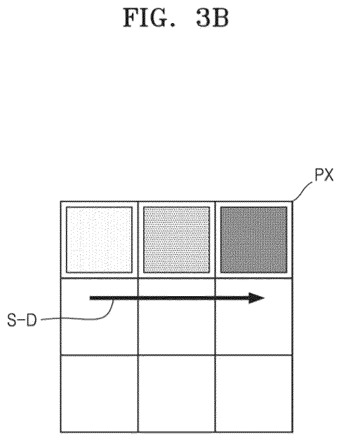

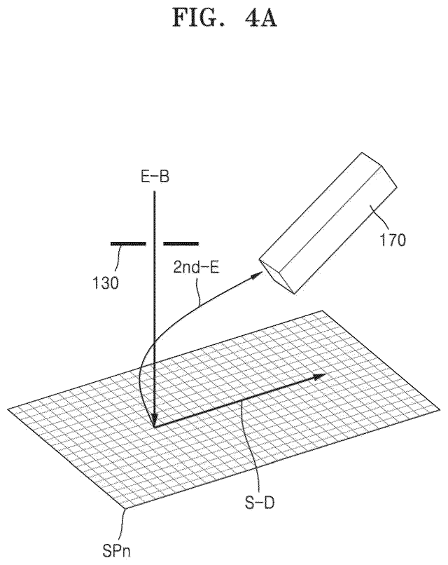

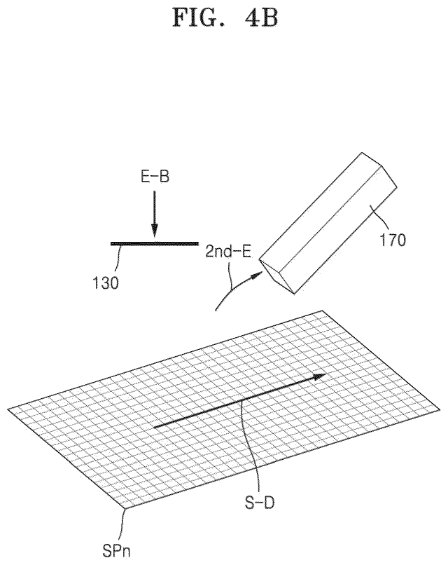

FIG. 2 is a conceptual diagram illustrating the method of improving an SEM image of FIG. 1 in conjunction with SEM equipment according to one or more embodiments. FIGS. 3A and 3B are diagrams illustrating a cause by which noise is included in an SEM image, according to one or more embodiments. FIGS. 4A and 4B are diagrams illustrating a method of reducing or canceling noise in an SEM image, according to one or more embodiments.

Referring to FIGS. 2, 3A, and 3B, the SEM equipment 100 may obtain SEM images by imaging a pattern portion at several positions of a sample SPn. As shown in FIG. 2, the SEM equipment 100 may include an electron gun 110, a first lens 120, an aperture 130, a second lens 140, a scanning coil 150, a third lens 160, and a detector 170.

The electron gun 110 may use, for example, a Schottky-type or thermal-field-emission-type electron gun. An acceleration voltage may be applied to the electron gun 110 to emit electrons (i.e., an electron beam (E-beam)). The first lens 120 may correspond to an anode electrode as an acceleration electrode. For example, the E-beam may be accelerated by a voltage applied to the electron gun 110 and the first lens 120.

The aperture 130 may be between the first lens 120 and the second lens 140. An aperture block coil 135 may be on the aperture 130. An aperture signal AW may be applied to the aperture block coil 135, and for each interval of the aperture signal AW, the E-beam may be emitted on the sample SPn by passing through the aperture 130 or cannot reach the sample SPn by being blocked by the aperture 130.

The second lens 140 may focus and accelerate the E-beam. The second lens 140 may be, for example, a magnetic lens and include two lenses. The scanning coil 150 may be above the third lens 160. The scanning coil 150 may allow the E-beam to one-dimensionally or two-dimensionally scan the sample SPn (e.g., a sample wafer). For example, when a high frequency control signal is applied from a scanning circuit 190 to the scanning coil 150, the E-beam may one-dimensionally or two-dimensionally scan the sample SPn by an electromagnetic force. The third lens 160 may correspond to an objective lens. The third lens 160 may focus the E-beam biased by the scanning coil 150 on the sample SPn.

The detector 170 may detect secondary electrons 2nd-E generated from the sample SPn due to the irradiation of sample SPn by the E-beam. The detector 170 may be, for example, a photo multiplier tube (PMT). However, the detector 170 is not limited to the PMT. In one or more embodiments, an additional detector may be below the third lens 160. The additional detector may detect electrons reflected (back-scattered) due to the irradiation of the sample SPn by the E-beam.

The sample SPn may be on an inspection stage. The inspection stage may move the sample SPn in the x direction, the y direction, or the z direction through linear movement in the x direction, the y direction, or the z direction, respectively.

An SEM image measurement method using the SEM equipment 100 may be performed as described below in one or more embodiments. When an E-beam scans the sample SPn, a generated amount of the secondary electrons 2nd-E may vary according to the unevenness of the surface of the sample SPn. The generated secondary electrons 2nd-E may be collected using the detector 170. The amount of the secondary electrons 2nd-E may be amplified to a voltage signal, and the difference between voltage signals may be represented for each position on an XY space to form the surface shape of the sample SPn as an image (i.e., an SEM image).

The resolution of the SEM equipment 100 may be about 1 nm, and SEM image measurement using the SEM equipment 100 may be requisite to measure a semiconductor fine pattern. Recently, along with an increase in the necessity of SEM image measurement on a semiconductor fine pattern, the demand for measurement of a large amount of SEM images at a high speed has increased. However, when a measurement speed is increased, a completely new signal may not be received as a voltage signal of the detector 170, and a previous pixel signal may influence an SEM image such that a virtual image corresponding to about several pixels is generated in the SEM image. In particular, because a virtual image of an edge portion of a pattern largely influences CD measurement on a semiconductor fine pattern, it is significant to remove a virtual image from an SEM image such that an accurate SEM image is generated. In the method of improving an SEM image according to one or more embodiments, a noise correlation length may be determined through noise correlation analysis or noise analysis on an SEM image of one frame and fed back to the aperture wave module 180 to adjust the aperture signal AW such that a virtual image generated by the detector 170 is removed by adjusting a generation period of secondary electrons 2nd-E, thereby generating an SEM image from which the virtual image has been removed.

Referring to FIGS. 4A and 4B, as shown in FIG. 2, the aperture signal AW may be a periodic pulse signal. That is, when the period of the aperture signal AW is T, it may be realized that t1+t2=T. t1 may denote a time corresponding to an interval during which an E-beam E-B cannot pass through the aperture 130, and t2 may denote a time corresponding to an interval during which the E-beam E-B passes through the aperture 130. In addition, although FIG. 2 shows that T corresponds to one pixel, T does not necessarily correspond to one pixel.

As shown in FIG. 4A, for t2 of the aperture signal AW, the electromagnetic field of the aperture block coil 135 may be turned off such that the E-beam E-B passes through the aperture 130. The E-beam E-B having passed through the aperture 130 may be emitted on the sample SPn to generate secondary electrons 2nd-E, and the generated secondary electrons 2nd-E may be focused on and detected by the detector 170.

As shown in FIG. 4B, for t1 of the aperture signal AW, the electromagnetic field of the aperture block coil 135 may be turned on to change the direction of the E-beam E-B such that the E-beam E-B is blocked by the aperture 130 due to the electromagnetic field. That is, the E-beam E-B cannot pass through the aperture 130 such that the E-beam E-B is not emitted on the sample SPn, and accordingly, the secondary electrons 2nd-E cannot be generated.

As described above, the amount of the detected secondary electrons 2nd-E may be converted into a voltage signal by the detector 170 and mapped to the XY space such that an SEM image is generated. Through noise analysis on the generated SEM image, an inter-pixel correlation length (i.e., a noise correlation length) may be determined to check whether a residual signal component remains in the signal detected by the detector 170. Herein, the residual signal component may indicate inter-pixel interference noise. In other words, a residual signal component of an adjacent previous pixel may act as noise in a signal of a current pixel.

In FIGS. 2 and 3B, the SEM image displayed on a monitor 175 at the rear end of the detector 170 is shown in a pixel form. In the SEM image, a pixel is displayed gradually darker to the right in a scan direction S-D, and as a pixel is dark, the voltage of the pixel may be high. In addition, in FIG. 2, the voltages of pixels may be represented as a waveform above the SEM image, and the voltages of pixels may increase in a sawtooth waveform to the right in the scan direction S-D. Residual voltages of previous pixels may be added to subsequent pixels such that a voltage gradually increases. In addition, the noise correlation length determination may confirm that there is interference in about three pixels in the scan direction S-D. As a reference, although FIGS. 2 and 3B show the SEM image in a 3×3 array form to describe interference among three pixels, an actual SEM image of one frame may include thousands or more of pixels.

When the noise correlation length is determined, the determined noise correlation length may be fed back to the aperture wave module 180 to adjust the length of t1. For example, when t1 is increased, a blocking time of the E-beam E-B by the aperture 130 may increase. Because fewer secondary electrons 2nd-E are generated from the sample SPn in correlation with the increased blocking time of the E-beam E-B, the standby time of the detector 170 may also increase, thereby ensuring a sufficient time to remove the residual voltage of the detector 170. Thereafter, noise analysis may be performed again, and when inter-pixel interference remains (i.e., when a noise correlation length is determined), a feedback process of adjusting t1 may be repeated again. When an ideal SEM image without inter-pixel interference is generated, a noise correlation length may be determined as 0 or substantially 0 in noise analysis, and a feedback process to the aperture wave module 180 may end. However, even in the SEM image without inter-pixel interference, white noise may be still included. Therefore, a process of canceling white noise may be performed thereafter.

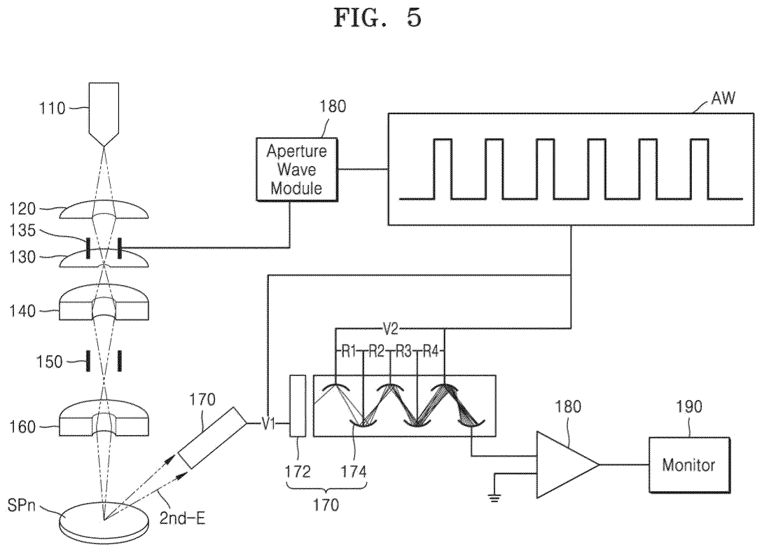

FIG. 5 is a diagram illustrating a method of improving an SEM image in conjunction with SEM equipment according to one or more embodiments. Description of aspects the same as or similar to those described above in FIGS. 1 to 4B may be omitted.

Referring to FIG. 5, the method of improving an SEM image according to one or more embodiments may further include a method of adjusting the voltage of the detector 170 in addition to the method of adjusting the aperture signal AW through the aperture wave module 180, thereby further ensuring the removal of inter-pixel interference. That is, a noise correlation length may be completely 0. Particularly, when the detector 170 is a PMT, the detector 170 may not be activated for t1 of the aperture signal AW by adjusting a voltage V1 to be applied to a cathode layer 172 at an entrance side and a voltage V2 to be applied to an embedded dynode electrode 174. That is, the detector 170 may not detect secondary electrons 2nd-E for t1.

In one or more embodiments, only the method of adjusting the voltage of the detector 170 may be used without using the method of adjusting the aperture signal AW. That is, inter-pixel interference may be removed by deactivating the detector 170 through voltage adjustment for t1 of the aperture signal AW without adjusting the aperture signal AW. However, embodiments are not limited thereto, and inter-pixel interference may be removed through various interworking methods between the voltage of the aperture signal AW and an operation of the detector 170.

FIGS. 6A to 6C are diagrams illustrating a method of determining a noise correlation length, according to one or more embodiments. In the graph of FIG. 6C, the X-axis indicates a relative distance d, the Y-axis indicates correlation Cor., and both have no units.

Referring to FIG. 6A, if it is possible to obtain both an image containing noise and an image not containing noise from a same object to be detected by adjusting the number of frames, only pure noise may be obtained by determining the signal difference between the two images. In FIG. 6A, a first SEM image S1 may correspond to an image containing noise, a second SEM image S2 may correspond to an image not containing noise, and an image N1 may correspond to a pure noise image. FIG. 6A shows that the pure noise image N1 may be obtained by subtracting the second SEM image S2 from the first SEM image S1.

Referring to FIG. 6B, if an image not containing noise cannot be obtained, because noise cannot be obtained in the method shown in FIG. 6A, the noise may be determined using only an image containing noise. Because most components of a noise signal correspond to a high frequency signal, an approximate noise component may be determined by applying a high-pass filter (HPF) to the image containing noise.

For example, a Gaussian kernel may be used as the HPF, and the Gaussian kernel is shown in an image form in FIG. 6B. That is, when the HPF as the Gaussian kernel is applied to the first SEM image S1 containing noise, a noise image N2 may be obtained. In FIG. 6B, ‘*’ is a symbol indicating a convolutional operation. In one or more embodiments, a method of obtaining an approximate image not containing noise by using an HPF, and obtaining a noise image by subtracting the approximate image from an image containing noise may be used.

Referring to FIG. 6C, when a noise signal is obtained using the method of FIG. 6A or 6B, a noise correlation coefficient (ρ_{X,Y}) may be determined using the definition of a correlation of two variables (X, Y) as in Equation (1).

$${ρ}_{X , Y} = corr ( X , Y ) = cov ( X , Y ) / {σ}_{X} {σ}_{Y} = E [ ( X - {μ}_{X} ) ( Y - {μ}_{Y} ) ] / {σ}_{X} {σ}_{Y} , if {σ}_{X} {σ}_{Y} > 0 \qquad ( 1 )$$

In Equation (1), corr(X, Y) has the same meaning as the noise correlation coefficient (ρ_{X,Y}), cov(X, Y) denotes the covariance of the two variables (X, Y), μ_{X} and μ_{Y} denote the averages of the variable X and the variable Y, respectively, σ_{X} and σ_{Y} denote the standard deviations of the variable X and the variable Y, respectively, and E denotes an average.

Thereafter, a correlation corresponding to the relative distance d may be determined. If the correlation of the relative distance d is determined, the relationship between X and Y in Equation (1) may be based on pieces of noise with a distance of d. For example, if X indicates the value of one position of a pure noise signal, Y may indicate the positions of noise signals separated by d from X. Then, because σ_{X} and σ_{Y} denote the standard deviations of noise, σ_{X} and σ_{Y} become the strengths of the noise regardless of a distance, and only cov(X, Y) may be determined according to a desired distance. In this case, if an original image is shifted by the relative distance d, the distance between the original image and the shifted image is d, and thus, cov(X, Y) may be obtained by subtracting averages (μ_{X}, μ_{Y}) from the original image and the shifted image, multiplying the subtraction results, and then obtaining averages of the multiplication results, respectively.

Through a corresponding process, the correlation when the relative distance d is 1, 2, 3, . . . may be determined. As shown in the graph of FIG. 6C, a correlation decreases as the relative distance d increases, and in this case, the presence/absence of correlation may be determined based on a certain reference value, and a correlation length may be reversely determined through the relative distance d. Particularly, in the graph of FIG. 6C, a reference value Rcor is represented as a black solid line. Therefore, it may be determined based on the reference value Rcor that there is a correlation at an upper portion and there is no correlation at a lower portion. In addition, because there is no correlation at the relative distance d greater than or equal to 5, it may be determined that a correlation length at the relative distance d greater than or equal to 5 is 0.

FIG. 7 is a flowchart illustrating a method of improving an SEM image according to one or more embodiments. Description of aspects the same as or similar to those above may be omitted.

Referring to FIG. 7, the method of improving an SEM image according to one or more embodiments may repeatedly perform operation S210 of measuring an SEM image of one frame to operation S235 of adjusting an aperture signal until a noise correlation length is substantially 0. Operation S210 of measuring an SEM image of one frame to operation S235 of adjusting an aperture signal may be the same as operation S110 of measuring an SEM image of one frame to operation S135 of adjusting an aperture signal in the Method of improving an SEM image of FIG. 1, respectively.

If the noise correlation length is substantially 0 (YES in operation S230), quality evaluation on the SEM image of the one frame may be performed in operation S240. For example, the quality evaluation on the SEM image of the one frame may be performed through a PSNR determination. However, the quality evaluation on the SEM image of the one frame is not limited to the PSNR determination. In addition, the quality evaluation on the SEM image of the one frame may be digitized and set as a reference score. For example, the PSNR determination value for the SEM image of the one frame may be set as the reference score.

After the quality evaluation on the SEM image of the one frame, in operation S250, SEM images of N frames may be measured while changing the measurement condition of the SEM equipment 100 and quality evaluation on the SEM images of the N frames may be performed. Herein, N may be preset to an integer greater than or equal to 2. For example, N may be set to tens or hundreds.

When measuring the SEM images of the N frames, the aperture signal AW may be constant. For example, the same waveform of the aperture signal AW as that when the SEM image of the one frame of which the noise correlation length is substantially 0 was measured may be applied to measure the SEM images of the N frames. Alternatively, before the quality evaluation on each of the SEM images of the N frames, a process of canceling white noise in each of the SEM images of the N frames may be performed. The quality evaluation on each of the SEM images of the N frames may be performed through, for example, a PSNR determination. Operation S250 of performing measurement and quality evaluation on the SEM images of the N frames is described in more detail with reference to FIG. 8.

The quality evaluation on the SEM images of the N frames may be performed by accumulating the SEM images at one-frame intervals and performing quality evaluation on the accumulated SEM image. Because white noise is random noise, when a plurality SEM images are accumulated, pieces of white noise may be offset with each other and canceled, and accordingly, the quality of the accumulated SEM image may be improved.

After the performing of the quality evaluation on the SEM images of the N frames, a measurement condition of the SEM equipment 100 corresponding to an SEM image of a best-quality frame may be selected as an SEM image measurement method in operation S260.

The method of improving an SEM image according to one or more embodiments may generate an SEM image, from which interference noise has been canceled, by canceling noise due to interference between adjacent pixels through a process of adjusting an aperture signal by determining a noise correlation length through noise analysis and feeding the noise correlation length back to the aperture wave module 180. In addition, an optimal SEM image measurement method may be selected through a process of measuring SEM images of a plurality of frames while maintaining an aperture signal by which a noise correlation length is 0 or substantially 0, changing the measurement condition of the SEM equipment 100, canceling white noise for each frame, and evaluating the quality of each SEM image. An SEM image with the best quality may be obtained through the selected optimal SEM image measurement method. Therefore, the method of improving an SEM image according to one or more embodiments may obtain an SEM image with the best quality for a semiconductor pattern through an optimal SEM image measurement method, thereby significantly improving the consistency of CD measurement on the semiconductor pattern.

FIG. 8 is a flowchart illustrating performing measurement and quality evaluation on SEM images of N frames according to one or more embodiments. Description of aspects the same as or similar to those above may be omitted.

Referring to FIG. 8, in the method of improving an SEM image according to one or more embodiments, operation S250 of performing the measurement and quality evaluation on the SEM images of the N frames may first include operation S251 of setting n to 1. Herein, n may be an integer of 1 to N and may be a value corresponding to a frame.

Next, an SEM image of an nth frame may be measured in operation S252. For example, because n is set to 1, an SEM image of a first frame may be measured. In the measurement of the SEM image of the first frame, the aperture signal AW of which the noise correlation length is 0 may be applied. In addition, in subsequent measurement of an SEM image of another frame, the aperture signal AW of which the noise correlation length is 0 may also be applied.

After the measuring of the SEM image of the nth frame, white noise in the SEM image of the nth frame may be canceled in operation S254. For example, in the method of improving an SEM image according to one or more embodiments, white noise may be canceled through unsupervised learning. The unsupervised learning for canceling white noise may be referred to as white noise-based unsupervised learning. Compared to the white noise-based unsupervised learning, the aforementioned unsupervised learning for determining a noise correlation length may be referred to as predictive unsupervised learning (i.e., unsupervised learning for predicting a noise correlation length).

A white noise canceling method is not limited to the unsupervised learning. For example, various methods, such as a method of canceling white noise by using a dither signal and a method of canceling white noise by accumulating SEM images of a plurality of frames, may be used to cancel white noise.

After the canceling of the white noise, quality evaluation on the SEM image of the nth frame may be performed in operation S256. The quality evaluation on the SEM image may be performed through a PSNR determination. However, the quality evaluation on the SEM image is not limited to the PSNR determination. For the method of canceling white noise by accumulating SEM images of a plurality of frames, the SEM images may be accumulated in a one-frame interval, and quality evaluation on the accumulated SEM image may be performed.

Thereafter, it may be determined in operation S258 whether n is less than N. As described above, N may be an integer greater than or equal to 2, may indicate the number of frames to be measured and evaluated, and may be preset to tens or hundreds.

If n is less than N (YES in operation S258), in operation S259, n may be increased by 1 and at least one measurement condition of the SEM equipment 100 is changed. However, the at least one measurement condition may not include the aperture signal AW. In other words, in the measurement on the SEM images of the N frames, the aperture signal AW may be fixed without being changed. Thereafter, the method of improving an SEM image may repeat, and operation S252 of measuring the SEM image of the nth frame, as well as subsequent operations may be performed again for the SEM image of the next frame.

If n is N or greater (NO in operation S258), the method of improving an SEM image may proceed with operation S260 of selecting an SEM image measurement method. As described above, in operation S260 of selecting an SEM image measurement method, a measurement condition of the SEM equipment 100 corresponding to the SEM image of a best-quality frame among the evaluated SEM images of the N frames may be selected as the SEM image measurement method.

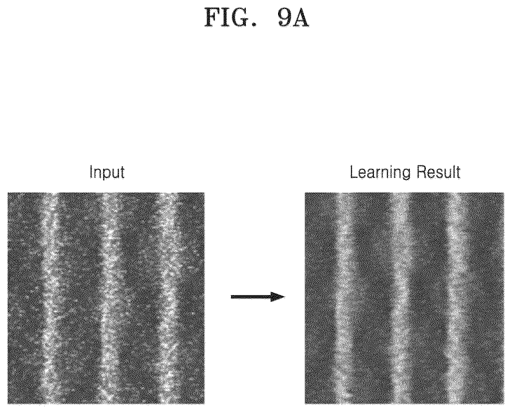

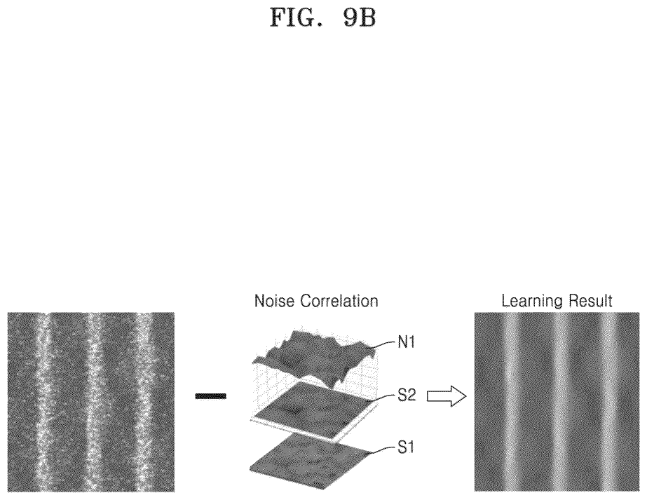

FIG. 9A illustrates an SEM image containing noise due to an inter-pixel interference signal and a learning result image obtained through unsupervised learning based on the SEM image. FIG. 9B illustrates an image undergoing a noise cancelation process and a learning result image obtained through unsupervised learning based on the noise-canceled SEM image according to one or more embodiments

As shown in FIG. 9A (e.g., a comparative example), for unsupervised learning through an SEM image containing noise (i.e., white noise-based unsupervised learning), due to the presence of noise by an inter-pixel interference signal, noise is still included in an SEM image as a learning result, and thus, an accurate SEM image cannot be obtained. That is, even after learning, an SEM image including a virtual signal of the detector 170 may be obtained. The SEM image including the virtual signal may cause an error in CD measurement. In addition, the noise in the SEM image as a learning result may include both noise due to an inter-pixel interference signal corresponding to the virtual signal and white noise. That is, the white noise may not be completely canceled either because of the noise due to an inter-pixel interference signal.

However, as shown in FIG. 9B (an example corresponding to one or more embodiments), when unsupervised learning is performed based on a noise-canceled SEM image, an accurate SEM image, from which both noise due to an inter-pixel interference signal and white noise have been completely canceled, may be obtained. That is, the virtual signal of the detector 170 may be removed to obtain a high-quality SEM image. In FIG. 9B, the depicted noise correlation shows that the first SEM image S1 containing noise is divided into the second SEM image S2 not containing noise and the pure noise image N1, and a symbol ‘−’ between an SEM image and the noise correlation may indicate a process of generating the second SEM image S2 not containing noise by subtracting the pure noise image N1 from the first SEM image S1 containing noise. In addition, an SEM image as a learning result may correspond to a result obtained by performing unsupervised learning on the second SEM image S2 not containing noise. As a reference, the white noise-based unsupervised learning one or more embodiments may be achieved through self-image learning. In the self-image learning, learning may be performed by comparing regions in an own frame without comparing the own frame to another frame.

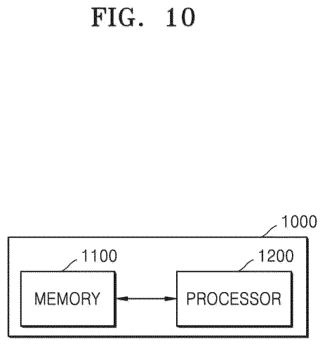

FIG. 10 is a block diagram of an SEM image measurement system according to an embodiment.

As shown in FIG. 10, the SEM image measurement system 1000 may include a memory 1100 and a processor 1200. However, the configuration shown in FIG. 10 is an example for implementing the embodiments, and other hardware and software configurations may be additionally included in the SEM image measurement system 1000 as will be understood to one of ordinary skill in the art from the disclosure herein. According to one or more embodiments, the SEM image measurement system 1000 may be implemented in the form of an electronic device.

The SEM image measurement system 1000 according to one or more embodiments may be configured to perform operations such as measuring an SEM image of one frame, determining a noise correlation length with respect to the SEM image, and based on the noise correlation length being greater than 0, adjusting an aperture signal of an SEM equipment.

The memory 1100 may store commands or data related to at least one other component of the SEM image measurement system 1000. Also, the memory 1100 may be accessed by the processor 1200, and reading/writing/modifying/deleting/updating of data may be performed by the processor 1200.

The term memory may include the memory 1100, a read-only memory (ROM) or a random access memory (RAM) in the processor 1200, or a memory card (e.g., a micro secure digital (SD) card or a memory stick) mounted in the SEM image measurement system 1000. In addition, the memory 1100 may store programs and data for configuring various screens to be displayed on a display area of a display.

According to an example, the memory 1100 may include a non-volatile memory capable of maintaining stored information even if power supply is interrupted, and a volatile memory requiring continuous power supply to maintain stored information. For example, the non-volatile memory may be implemented as at least one of one time programmable ROM (OTPROM), programmable ROM (PROM), erasable and programmable ROM (EPROM), electrically erasable and programmable ROM (EEPROM), mask ROM, or flash ROM, and the volatile memory may be implemented as at least one of dynamic RAM (DRAM), static RAM (SRAM), or synchronous dynamic RAM (SDRAM).

The processor 1200 may be electrically connected to the memory 1100 to control all operations and functions of the SEM image measurement system 1000.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments including, but not limited to, FIG. 10, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of improving a scanning electron microscope (SEM) image, the method comprising:
(a) measuring a first SEM image;
(b) determining a noise correlation length with respect to the first SEM image;
(c) based on the noise correlation length being greater than 0, adjusting an aperture signal of an SEM equipment; and
repeating (a), (b) and (c) until the noise correlation length is substantially 0.

2. The method of claim 1, wherein the aperture signal corresponds to a periodic pulse signal for adjusting electrons from an electron gun in the SEM equipment to pass through an aperture, and
wherein t1+t2=T, where T is a period of the aperture signal, t1 is an interval during which the electrons cannot pass through the aperture, and t2 is an interval during which the electrons pass through the aperture.

3. The method of claim 1, wherein the operation (b) of determining the noise correlation length comprises determining the noise correlation length based on unsupervised learning on the first SEM image.

4. The method of claim 1, wherein the operation (b) of determining the noise correlation length comprises:
obtaining a noise image by applying a high-pass filter to the first SEM image; and
determining a correlation length between adjacent noise images by iteratively shifting a pixel position in the noise image by one pixel.

5. The method of claim 1, wherein the operation (b) of determining the noise correlation length comprises:
obtaining a reference image by applying a high-pass filter to the first SEM image;
obtaining a noise image based on a difference between the reference image and the first SEM image; and
determining a correlation length between adjacent noise images by iteratively shifting a pixel position in the noise image by one pixel.

6. The method of claim 1, further comprising, based on the noise correlation length being substantially 0:
setting a reference score by performing a first quality evaluation on the first SEM image;
measuring SEM images of N frames while fixing the aperture signal and changing a measurement condition of the SEM equipment, N being an integer that is greater than or equal to 2;
performing a second quality evaluation on the SEM images of the N frames; and
selecting a measurement condition corresponding to an SEM image of a best-quality frame among the SEM images of the N frames.

7. The method of claim 6, wherein the performing of the second quality evaluation on the SEM images of the N frames comprises:
setting n to 1, n being an integer corresponding to a frame;
measuring an SEM image of an nth frame;
canceling white noise in the SEM image of the nth frame;
performing a third quality evaluation on the SEM image of the nth frame; and
based on n being less than N, increasing n by 1 and changing a measurement condition of the SEM equipment,
wherein, after the changing of the measurement condition of the SEM equipment, operations (a), (b) and (c) are performed with the SEM image of the nth frame.

8. The method of claim 7, wherein the canceling of the white noise comprises canceling the white noise based on unsupervised learning on the SEM image of the nth frame.

9. The method of claim 7, wherein the canceling of the white noise comprises accumulating a plurality of frames and canceling white noise in an SEM image in which the plurality of frames are accumulated, and
wherein the first quality evaluation on the SEM image is performed on the white noise-canceled SEM image.

10. The method of claim 6, wherein the first quality evaluation on the SEM image is performed based on a peak signal-to-noise ratio (PSNR) determination.

11. A method of improving a scanning electron microscope (SEM) image, the method comprising:
measuring a first SEM image;
determining a noise correlation length with respect to the first SEM image; and
based on the noise correlation length being substantially 0:
setting a reference score by performing a first quality evaluation on the first SEM image;
fixing an aperture signal;
setting n to 1, n being an integer corresponding to a frame;
measuring an SEM image of an nth frame;
canceling white noise in the SEM image of the nth frame;
performing a second quality evaluation on the SEM image of the nth frame;
based on n being less than N, increasing n by 1 and changing a measurement condition of an SEM equipment, N being an integer that is greater than or equal to 2;
based on n being greater than or equal to N, selecting a measurement condition corresponding to an SEM image of a best-quality frame among SEM images of the N frames; and
measuring the SEM image of the nth frame based on the selected measurement condition of the SEM equipment.

12. The method of claim 11, further comprising, based on the noise correlation length being greater than 0, adjusting the aperture signal of the SEM equipment,
wherein the aperture signal corresponds to a signal for adjusting electrons from an electron gun in the SEM equipment to pass through an aperture, and
wherein t1+t2=T, where T is a period of the aperture signal, t1 is an interval during which the electrons cannot pass through the aperture, and t2 is an interval during which the electrons pass through the aperture.

13. The method of claim 11, wherein the determining of the noise correlation length comprises determining the noise correlation length based on unsupervised learning on the first SEM image.

14. The method of claim 11, wherein the determining of the noise correlation length comprises:
one of obtaining a noise image by applying a high-pass filter to the first SEM image, and obtaining a noise image by obtaining a reference image and subtracting the reference image from the first SEM image; and
determining a correlation length between adjacent noise images by iteratively shifting a pixel position in the noise image by one pixel.

15. The method of claim 11, wherein the canceling of the white noise comprises canceling the white noise based on unsupervised learning on the SEM image of the nth frame.

16. The method of claim 11, wherein the canceling of the white noise comprises accumulating a plurality of frames and canceling white noise in an SEM image in which the plurality of frames are accumulated, and
performing a quality evaluation on the white noise-canceled SEM image.

17. The method of claim 11, wherein the first quality evaluation on the first SEM image is performed based on a peak signal-to-noise ratio (PSNR) determination.

18. A method of improving a scanning electron microscope (SEM) image, the method comprising:
measuring a first SEM image;
determining a noise correlation length with respect to the first SEM image based on unsupervised learning; and
based on the noise correlation length being substantially 0:
setting a reference score by performing a first quality evaluation on the first SEM image;
performing measurement and second quality evaluation on SEM images of N frames while fixing an aperture signal and changing a measurement condition; and
measuring an SEM image based on the changed measurement condition.

19. The method of claim 18, further comprising, based on the noise correlation length being greater than 0, adjusting the aperture signal of an SEM equipment,
wherein the aperture signal corresponds to a signal for adjusting electrons from an electron gun in the SEM equipment to pass through an aperture, and
wherein t1+t2=T, where T is a period of the aperture signal, t1 is an interval during which the electrons cannot pass through the aperture, and t2 is an interval during which the electrons pass through the aperture.

20. The method of claim 18, wherein the performing of the measurement and the second quality evaluation on the SEM images of the N frames comprises:
setting n to 1, n being an integer corresponding to a frame;
measuring an SEM image of an nth frame;
canceling white noise in the SEM image of the nth frame based on unsupervised learning;
performing a third quality evaluation on the SEM image of the nth frame;
based on n being less than N, increasing n by 1 and changing the measurement condition of the SEM equipment;
after the changing of the measurement condition of the SEM equipment, measuring the SEM image of the nth frame; and
based on n being greater than or equal to N after the performing of the second quality evaluation on the SEM images of the N frames, selecting a measurement condition corresponding to an SEM image of a best-quality frame among the SEM images of the N frames.
